(19) United States
(12) Patent Application Publication
(10) Pub. No.: US 2025/0220921 A1
(43) Pub. Date: Jul. 3, 2025

(54) ENHANCING DEVICE PERFORMANCE BY MITIGATION OF OXYGEN MIGRATION IN HAFNIUM OXIDE BASED MATERIAL SYSTEMS

(71) Applicant: Intel Corporation, Santa Clara, CA (US)

(72) Inventors: Mahmut Sami Kavrik, Hillsboro, OR (US); Sou-Chi Chang, Portland, OR (US); Nazila Haratipour, Portland, OR (US); Sarah Atanasov, Beaverton, OR (US); Christopher Neumann, Portland, OR (US); Matthew Metz, Portland, OR (US); Marko Radosavljevic, Portland, OR (US); Uygar Avci, Portland, OR (US); Jack Kavalieros, Portland, OR (US)

(73) Assignee: Intel Corporation, Santa Clara, CA (US)

(21) Appl. No.: 18/400,901

(22) Filed: Dec. 29, 2023

(51) Int. Cl. H10B 53/30; H01L 21/28; H01L 29/51; H01L 29/66; H01L 29/78; H10B 51/30

(52) U.S. Cl. CPC H10B 53/30; H10B 51/30; H10D 30/0415; H10D 30/701; H10D 64/033; H10D 64/689

(57) ABSTRACT

Apparatuses, systems, and techniques related to ferroelectric material systems including hafnium oxide-based ferroelectric layers are described. A ferroelectric material system includes an oxide layer on the hafnium oxide-based ferroelectric layer, and an oxygen migration mitigation layer on the oxide layer. The oxygen migration mitigation layer is niobium nitride, tantalum nitride, ruthenium oxide, molybdenum, tungsten, ruthenium or palladium, and a metallic electrode is formed on the oxygen migration mitigation layer.

### BACKGROUND

Hafnium oxide and zirconium oxide-based ferroelectric/antiferroelectric material systems (e.g., ferroelectric oxides) are being considered for various devices including memory devices, ferroelectric field effect transistors (FeFETs), ferroelectric tunnel junctions (FTJs), and others, to be deployed in in memory systems, neuromorphic systems, and other computing systems due to the non-volatile nature of the material. Compatibility with existing complementary metal-oxide semiconductor (CMOS) technology makes these materials especially important.

However, stabilization of the distinct ferroelectric phase (i.e., the orthorhombic phase being ferroelectric while the tetragonal and monoclinic phases are dielectric) with well controlled device parameters in this material system is a major challenge due to the small energy difference between the various crystal phases, which determines the ferroelectric parameters of the material. Co-existence of multiple phases in the material modulates critical ferroelectric parameters such as coercive field (switching voltage), endurance, remnant polarization. In addition, the thickness of the ferroelectric oxide is correlated with the energy required to switch the polarization of the ferroelectrics (coercive field). Therefore, reduction of power consumption in devices is directly related with the ferroelectric oxide thickness. Scaling the ferroelectric oxide thickness deteriorates the device performance significantly with oxygen migration within the ferroelectric oxide as well as through the interfaces with the metal electrodes forming dead layers being main reason for these degradations. Moreover, ferroelectric oxide based ferroelectric devices capped with oxygen scavenging metals such as titanium nitride electrodes show significant degradation in polarization values as the device cycles billion of times and beyond, resulting in low endurance, which is a major concern for the implementation of these material systems.

It is with respect to these and other considerations that the present improvements have been needed. Such improvements may become critical as the desire to deploy advanced memory solutions becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1A illustrates a schematic of an example ferroelectric capacitor;

FIG. 1B illustrates a diagram of an example memory cell circuit;

FIG. 1C illustrates a plot showing polarization versus voltage for a capacitor deploying a ferroelectric material;

FIGS. 2A, 2B, and 2C illustrate cross-sectional side views of the formation of an example ferroelectric device structure having an oxide layer on a ferroelectric hafnium oxide-based material layer and an oxygen migration mitigation layer on the oxide layer;

FIG. 3 illustrates an example ferroelectric device structure similar to the ferroelectric device structure of FIG. 2C with an alternative oxygen migration mitigation layer on the oxide layer;

FIG. 4 illustrates a cross-sectional side view of an exemplary deep trench capacitor having an oxide layer on a ferroelectric hafnium oxide-based material layer and an oxygen migration mitigation layer on the oxide layer;

FIG. 5 illustrates a cross-section of an embedded dynamic random-access memory including the capacitor of FIG. 4;

FIG. 6 illustrates a cross-sectional side view of a multiple capacitor stacked memory device including capacitors having an oxide layer on a ferroelectric hafnium oxide-based material layer and an oxygen migration mitigation layer on the oxide layer;

FIG. 7 is a flow diagram illustrating methods for forming a device including an oxide layer on a ferroelectric hafnium oxide-based material layer and an oxygen migration mitigation layer on the oxide layer;

FIGS. 8A, 8B, 8C, 8D, 8E, 8F, 8G, and 8H are cross-sectional views of a device structure evolving as the methods of FIG. 7 are practiced;

FIG. 9 illustrates exemplary systems employing an IC die including a device having an oxide layer on a ferroelectric hafnium oxide-based material layer and an oxygen migration mitigation layer on the oxide layer; and

FIG. 10 is a functional block diagram of an electronic computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/−10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure. Herein, the term “predominantly” indicates not less than 50% of a particular material or component while the term “substantially pure” indicates not less than 95% of the particular material or component and the term “pure” indicates not less than 99% of the particular material or component. Furthermore, such terms may be used to indicate a material is not less than 50%, not less than 95%, or not less than 99% of a multi-component (i.e., two or more component system). Unless otherwise indicated, such material percentages are based on atomic percentage. As used herein, the terms “monolithic”, “monolithically integrated”, and similar terms indicate the components of the monolithic overall structure form an indivisible whole not reasonably capable of being separated.

Apparatuses, systems, device structures, and techniques are described herein related to ferroelectric material stacks deploying a hafnium oxide-based ferroelectric material and an oxygen migration mitigation layer over the hafnium oxide-based ferroelectric material for increased memory endurance and other device enhancements.

As discussed, hafnium oxide and zirconium oxide-based ferroelectric/antiferroelectric material systems (e.g., ferroelectric oxides) have promising characteristics for deployment in a variety of devices including memory devices, ferroelectric field effect transistors (FeFETs), ferroelectric tunnel junctions (FTJs), and others due to the non-volatile nature of the material systems. For example, the polarity of the material system, which can be switched, may be detected, and is maintained by the material system until it is again switched. As used herein, the term ferroelectric material or similar terms are inclusive of anti-ferroelectric material systems. However, in such ferroelectric material systems, stabilization of the distinct ferroelectric phase is a challenge. In some embodiments, the material system uses a hafnium oxide (HfO₂) based ferroelectric material. Hafnium oxide has been found to be ferroelectric when doped with, for example, zirconium. Such hafnium zirconium oxide (HZO) materials may be further doped with other elements such as lanthanum, silicon, aluminum, or others.

Notably, the orthorhombic phase of such material systems is ferroelectric while tetragonal and monoclinic phases are dielectric. For example, crystallization of the materials may not be single, meaning there are multiple phases in the material system (orthorhombic, tetragonal, and monoclinic). In hafnium oxide-based systems, there is a small energy difference between the phases, which makes it more likely each of the phases will be evident in the crystalline material. However, as discussed, only the ferroelectric orthorhombic phase has desirable device properties. To tune the material to include more of the orthorhombic phase, dopants within the material as well as interface materials of electrode materials may be selected. For example, dopants can be used to selectively stress the material and interface materials can be used for lattice alignment and other purposes to increase the orthorhombic phase in the device material.

As discussed further herein, in some embodiments, a ferroelectric material system includes a ferroelectric hafnium oxide-based material layer such as HZO doped with lanthanum (i.e., La:HZO), a niobium oxide layer or tantalum oxide layer on the ferroelectric hafnium oxide-based material layer, and an oxygen migration mitigation layer on the niobium oxide layer. For example, the oxygen migration mitigation layer may be niobium nitride, tantalum nitride, ruthenium oxide, tungsten, molybdenum, ruthenium, or palladium. An electrode may be formed on the oxygen migration mitigation layer. Notably, it has been observed that oxygen vacancies in the ferroelectric hafnium oxide-based material layer may cause deficiencies in the orthorhombic phase of the ferroelectric hafnium oxide-based material layer as well as degradation in polarization values of the ferroelectric hafnium oxide-based material layer as the material is cycled (i.e., switched) billion of times and beyond. For example, absent the oxygen migration mitigation layer, the electrode material, when formed directly on the ferroelectric hafnium oxide-based material layer, may form a dead layer between the electrode material and the ferroelectric hafnium oxide-based material layer with no ferroelectric properties and detrimental effects on the device performance. The dead layer may be due to oxygen vacancies, lattice misalignment, damage to the top surface of the ferroelectric hafnium oxide-based material layer, or others. The material systems discussed herein eliminate or mitigate such effects for improved ferroelectric properties and device performance including reduced degradation.

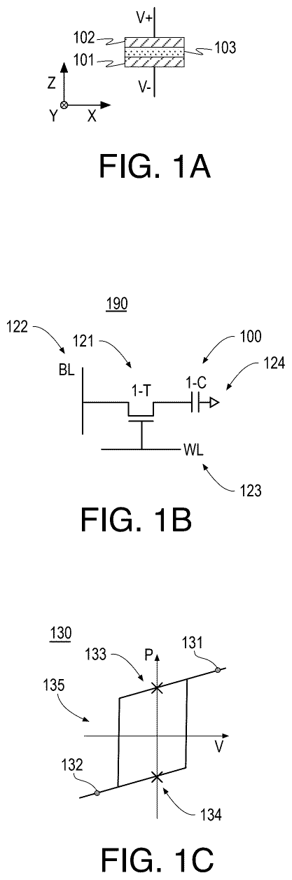

FIG. 1A illustrates a schematic of an example ferroelectric capacitor 100, arranged in accordance with at least some implementations of the present disclosure. As shown in FIG. 1A, ferroelectric (FE) capacitor 100 includes a material stack 103 between electrodes 101, 102. As discussed in detail herein, material stack 103 may include a multilayer stack including a ferroelectric hafnium oxide-based material layer, a niobium oxide layer on the ferroelectric hafnium oxide-based material layer, and a niobium nitride, tantalum nitride, ruthenium oxide, tungsten, molybdenum, or ruthenium on the hafnium oxide-based material layer. The niobium nitride, tantalum nitride, ruthenium oxide, tungsten, molybdenum, ruthenium, or palladium may be characterized as an oxygen migration mitigation layer or an interface layer, for example. Electrode 102 may include a metal layer on material stack 103. Notably, deployment of the niobium nitride, tantalum nitride, ruthenium oxide, tungsten, molybdenum, ruthenium, or palladium reduces oxygen migration and improves device performance. Although discussed herein with respect to a niobium oxide layer on the ferroelectric hafnium oxide-based material layer, other oxides such as a tantalum oxide may be used. In some embodiments, material stack 103 further includes a titanium oxide, aluminum oxide, or other material layer on electrode 101, with the ferroelectric hafnium oxide-based material layer being formed on the layer for enhancement of the orthorhombic phase of the ferroelectric hafnium oxide-based material layer. In some embodiments, electrode 101 is or includes a titanium nitride layer on which the orthorhombic phase promotion layer may be formed. However, electrode 101 may be any suitable material such as tantalum nitride, niobium nitride, ruthenium, tungsten, or molybdenum. The multi-layer nature of material stack 103 is not illustrated in FIG. 1A for the sake of clarity of presentation. Although illustrated with respect to deployment in ferroelectric capacitor 100, multi-layer material stack 103 may be deployed in any suitable device context.

FIG. 1B illustrates a diagram of an example memory cell circuit 190, arranged in accordance with at least some implementations of the present disclosure. As shown in FIG. 1B, FE capacitor 100 may be deployed in memory cell circuit 190, which provides a one capacitor-one transistor (1C-1T) architecture. Such 1C-1T architectures may be deployed in a variety of contexts including capacitor over bit line (COB) architectures (e.g., deep trench architectures), 3D array memory device architectures (e.g., vertically stacked capacitor architectures), or others. As shown, memory cell circuit 190 includes FE capacitor 100 and a transistor 121. Transistor 121 may have any suitable architecture. For example, transistor 121 may be a planar field effect transistor (FET), a FinFET, a gate all around (GAA) transistor (GAA-FET), or other. The gate of transistor 121 is controlled via a word line 123 and the source/drain of transistor 121 are coupled to FE capacitor 100 and a bit line 122. FE capacitor 100 is further coupled to a ground 124.

FIG. 1C illustrates a plot 130 showing polarization versus voltage for a capacitor deploying a ferroelectric material, arranged in accordance with at least some implementations of the present disclosure. Unlike a typical dielectric based capacitor, a ferroelectric capacitor uses polarization charge to store the memory states, where a positive polarization charge state 133 indicates, for example, a stored bit of “1” and a negative polarization charge state 134, indicate, for example, a stored bit of “0”. Plot 130 illustrates the hysteresis property of a ferroelectric material-based device. A ferroelectric material exhibits ferroelectricity, which is a property by which a spontaneous electric polarization can be revered by an electric field (e.g., applied voltage). For example, when a dielectric material is polarized, the induced polarization is proportional to the applied external electric field. Ferroelectric materials, on the other hand, demonstrate a spontaneous non-zero polarization even when the applied electric field is zero. As such, the spontaneous polarization may be reversed by an applied electric field in the opposite direction. This results in a hysteresis loop 135 because the polarization of a ferroelectric material is dependent not only on the present electric field but also on its history. Hysteresis loop 135 of plot 130 shows two stable operating positions or states for a ferroelectric capacitor, as discussed above: positive polarization charge state 133 and negative polarization charge state 134. These stable charge states 133, 134 indicate that the direction of polarization can be switched from one to another by application, for example, of positive switching voltage 131 and negative switching voltage 132.

As discussed, in some contexts, memory devices may deploy a ferroelectric material system. However, the ferroelectric material systems discussed herein may be deployed in any suitable context such as ferroelectric field effect transistors (FeFETs), ferroelectric tunnel junctions (FTJs), and others.

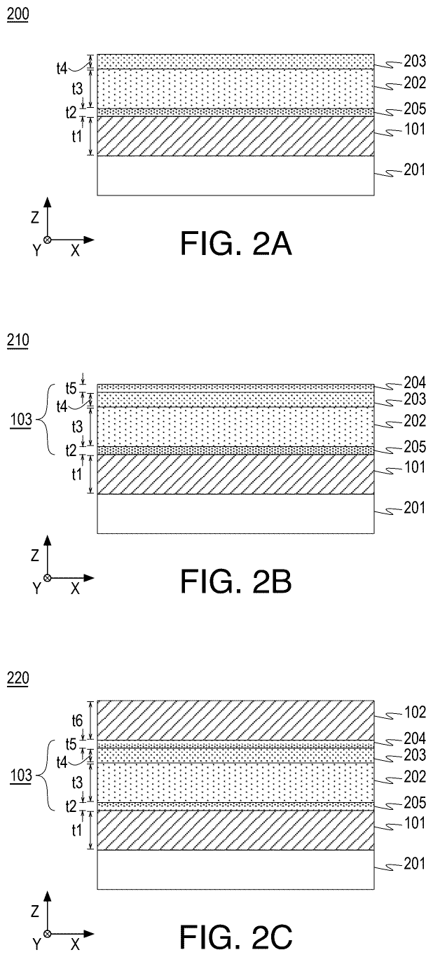

FIGS. 2A, 2B, and 2C illustrate cross-sectional side views of the formation of an example ferroelectric device structure 220 having an oxide layer on a ferroelectric hafnium oxide-based material layer and an oxygen migration mitigation layer on the oxide layer, arranged in accordance with at least some implementations of the present disclosure. As shown in FIG. 2A, a ferroelectric (FE) device structure 200 includes a substrate 201, bottom electrode 101, a seed layer 205, an FE hafnium oxide-based material layer 202, and a capping layer 203. Bottom electrode 101, seed layer 205, FE hafnium oxide-based material layer 202, and capping layer 203 may be formed using any suitable technique or techniques such as those discussed herein below.

In some embodiments, substrate 201 is a material used to manufacture integrated circuits inclusive of semiconductor materials such as, but not limited to, single crystal silicon, polycrystalline silicon and silicon on insulator (SOI). In some embodiments, substrate 201 includes other semiconductor materials such as germanium, silicon germanium, or a suitable group III-V or group III-N compound. Substrate 201 may also include semiconductor materials, metals, dopants, and other materials commonly found in semiconductor substrates. In some embodiments, substrate 201 includes a device layer (e.g., transistor devices), metallization stack(s), or other device layers.

Bottom electrode 101 may include any suitable conductive material such as a metal. In some embodiments, bottom electrode 101 is or includes a layer of titanium nitride (TiN, e.g., titanium and nitrogen) such that seed layer 205 or FE hafnium oxide-based material layer 202 is on the titanium nitride material. In some embodiments, bottom electrode is or includes tungsten (W), tantalum nitride (TaN, e.g., tantalum and nitrogen), niobium nitride (NbN, e.g., niobium and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt).

As shown, in some embodiments, FE device structure 200 includes seed layer 205 on electrode 101. In other embodiments, seed layer 205 is not deployed and FE hafnium oxide-based material layer 202 is on electrode 101. In some embodiments, seed layer 205 is or includes titanium oxide (TiO₂, e.g., titanium and oxygen). In some embodiments, seed layer 205 is or includes one of aluminum oxide (Al₂O₃, e.g., aluminum and oxygen), vanadium oxide (V₂O₃, e.g., vanadium and oxygen), tantalum oxide (Ta₂O₅, e.g., tantalum and oxygen), zirconium oxide (ZrO₂, e.g., zirconium and oxygen), silicon oxide (SiO₂, e.g., silicon and oxygen), or molybdenum oxide (MoO₃, e.g., molybdenum and oxygen). For example, seed layer 205 may promote the formation of the orthorhombic phase of FE hafnium oxide-based material layer 202 relative to the tetragonal and monoclinic phases. Although characterized as a seed layer, seed layer 205 may be characterized simply as a material layer, material, layer, or the like. Seed layer 205 may promote the growth of the orthorhombic phase or orthorhombic crystal system of FE hafnium oxide-based material layer 202.

As shown, FE hafnium oxide-based material layer 202 is on seed layer 205 or FE hafnium oxide-based material layer 202 is on electrode 101. As discussed, FE hafnium oxide-based material layer 202 is a ferroelectric material. FE hafnium oxide-based material layer 202 includes hafnium and oxygen and may further include one or more dopants. In some embodiments, FE hafnium oxide-based material layer 202 includes hafnium and oxygen, and one or more dopants including one or more of zirconium (Zr), silicon (Si), lanthanum (La), aluminum (Al), niobium (Nb), germanium (Ge), or scandium (Sc). In some embodiments, FE hafnium oxide-based material layer 202 includes hafnium, zirconium, and oxygen. For example, hafnium and oxygen may be HZO. In some embodiments, hafnium and oxygen FE hafnium oxide-based material layer 202 includes hafnium, zirconium, oxygen, and one or more additional dopants. In some embodiments, the additional dopant is one of silicon, aluminum, or lanthanum. In some embodiments, the additional dopant is lanthanum. In some embodiments, the additional dopant is one or more of silicon, lanthanum, aluminum, niobium, germanium, or scandium.

As discussed, FE hafnium oxide-based material layer 202 is adjacent electrode 101 with FE hafnium oxide-based material layer 202 being on electrode 101 or FE hafnium oxide-based material layer 202 being on seed layer 205, with seed layer 205 being on electrode 101. FE hafnium oxide-based material layer 202 is a ferroelectric material including hafnium and oxygen. In some embodiments, FE hafnium oxide-based material layer 202 further includes zirconium, silicon, lanthanum, aluminum, niobium, germanium, or scandium. In some embodiments, FE hafnium oxide-based material layer 202 includes hafnium, zirconium, and oxygen, and one or more of silicon, lanthanum, or aluminum.

As discussed, it is desirable for FE hafnium oxide-based material layer 202 to have a greater proportion thereof be an orthorhombic phase or orthorhombic crystal system relative to other phases such as tetragonal or monoclinic phases. In some embodiments, FE hafnium oxide-based material layer 202 is not less than 50 percent orthorhombic crystal system. In some embodiments, FE hafnium oxide-based material layer 202 is not less than 60 percent orthorhombic crystal system. FE hafnium oxide-based material layer 202 is not less than 80 percent orthorhombic crystal system. The orthorhombic crystal system may be induced in FE hafnium oxide-based material layer 202 by dopant selection, thermal annealing operations, and/or selection of the materials in FE device structure 200 such as those of electrode 101 and electrode 102, with titanium nitride, molybdenum, and tungsten being advantageous, as well as those of capping layer 203 and oxygen migration mitigation layer 204, which is discussed herein below. In addition or in the alternative, post atomic layer deposition (ALD) oxidation processes using ozone or oxygen plasma may improve the performance of FE device structure 200 by mitigating oxygen deficiencies in FE hafnium oxide-based material layer 202.

As shown, capping layer 203 is on FE hafnium oxide-based material layer 202. Capping layer 203 is an oxide that may provide oxygen for any oxygen vacancies in FE hafnium oxide-based material layer 202 and/or to provide oxygen for any oxygen gettering of other layers in the resultant material stack. Capping layer 203 may be any suitable oxide. In some embodiments, capping layer 203 is niobium oxide such that capping layer 203 includes niobium and oxygen. In some embodiments, capping layer 203 is or includes niobium pentoxide, Nb₂O₅. In some embodiments, capping layer 203 is or includes niobium dioxide, NbO₂. In some embodiments, capping layer 203 is or includes a combination of niobium pentoxide and niobium dioxide, NbO₂. In some embodiments, capping layer 203 is not less than 60 percent oxygen. In some embodiments, capping layer 203 is not less than 30 percent niobium and not less than 60 percent oxygen. In some embodiments, capping layer 203 is pure niobium oxide with not less than 60 percent oxygen and a balance (up to at least 99%) of niobium. In some embodiments, capping layer 203 is not less than 70 percent oxygen. In some embodiments, capping layer 203 is pure niobium oxide with not less than 70 percent oxygen and a balance (up to at least 99%) of niobium.

In some embodiments, capping layer 203 is tantalum oxide such that capping layer 203 includes tantalum and oxygen. In some embodiments, capping layer 203 is or includes tantalum pentoxide, Nb₂O₅. In some embodiments, capping layer 203 is not less than 70 percent oxygen. In some embodiments, capping layer 203 is not less than 25 percent tantalum and not less than 70 percent oxygen. In some embodiments, capping layer 203 is pure tantalum pentoxide with not less than 70 percent oxygen and a balance (up to at least 99%) of tantalum.

As shown, bottom electrode 101, seed layer 205, FE hafnium oxide-based material layer 202, and capping layer 203 may have thicknesses t1, t2, t3, and t4, respectively. Such thicknesses t1, t2, t3, and t4 may be any suitable thicknesses. In some embodiments, thickness t1 of bottom electrode 101 is in the range of 5 to 20 nm. In some embodiments, thickness t1 of bottom electrode 101 is in the range of 5 to 15 nm. In some embodiments, thickness t1 of bottom electrode 101 is about 10 nm. In some embodiments, thickness t1 of bottom electrode 101 is not more than 10 nm. In some embodiments, thickness t2 of seed layer 205 is in the range of 0.2 to 2 nm. In some embodiments, thickness t2 of seed layer 205 is in the range of 1 to 2 nm. In some embodiments, thickness t2 of seed layer 205 is about 1 nm. In some embodiments, thickness t2 of seed layer 205 is not more than 2 nm. In some embodiments, thickness t3 of FE hafnium oxide-based material layer 202 is in the range of 5 to 20 nm. In some embodiments, thickness t3 of FE hafnium oxide-based material layer 202 is in the range of 5 to 15 nm. In some embodiments, thickness t3 of FE hafnium oxide-based material layer 202 is about 10 nm. In some embodiments, thickness t3 of FE hafnium oxide-based material layer 202 is not more than 10 nm. In some embodiments, thickness t4 of capping layer 203 is in the range of 1 to 4 nm. In some embodiments, thickness t4 of capping layer 203 is in the range of 1 to 2 nm. In some embodiments, thickness t4 of capping layer 203 is about 2 nm. In some embodiments, thickness t4 of capping layer 203 is not more than 2 nm.

FIG. 2B illustrates an example FE device structure 210 similar to FE device structure 200 after formation of oxygen migration mitigation layer 204. Oxygen migration mitigation layer 204 may be formed using any suitable technique or techniques such as those discussed herein below. Although characterized as an oxygen migration mitigation layer, oxygen migration mitigation layer 204 may be characterized simply as a material layer, material, layer, or the like.

As shown, oxygen migration mitigation layer 204 is on capping layer 203. Notably, the discussed degradation of the ferroelectric behavior of FE hafnium oxide-based material layer 202 based on oxygen migration inducing reduction in polarization values especially in advanced cycling of the device beyond million times may be reduced or eliminated by the deployment of oxygen migration mitigation layer 204. In some embodiments, such degradation reduction or elimination is provided by the combination of capping layer 203 and oxygen migration mitigation layer 204.

In some embodiments, oxygen migration mitigation layer 204 is or includes niobium nitride (NbN, e.g., niobium and nitrogen). Notably, niobium nitride is a diffusion barrier. Furthermore, niobium nitride is a metallic material that is suitable for subsequent formation of electrode 102 thereon. For example, oxygen migration mitigation layer 204 may be characterized as a portion of an electrode. In addition, niobium nitride advantageously does not increase the total oxide thickness of material stack 103 and avoids formation of a dead layer in material stack 103. In some embodiments, oxygen migration mitigation layer 204 is or includes niobium nitride such that oxygen migration mitigation layer 204 includes niobium and nitrogen. In some embodiments oxygen migration mitigation layer 204 is or includes approximately stoichiometric 1:1 niobium nitride, NbN. In some embodiments, oxygen migration mitigation layer 204 is not less than 45 percent niobium and not less than 45 percent nitrogen. In some embodiments, oxygen migration mitigation layer 204 is not less than 49 percent niobium and not less than 49 percent nitrogen. In some embodiments, oxygen migration mitigation layer 204 is pure niobium nitride with the sum of niobium and nitrogen percentages being at least 99%. In some embodiments, oxygen migration mitigation layer 204 is not less than 45 percent niobium and a balance (up to at least 99%) of nitrogen. In some embodiments, oxygen migration mitigation layer 204 is not less than 45 percent nitrogen and a balance (up to at least 99%) of niobium.

In some embodiments, oxygen migration mitigation layer 204 is or includes tantalum nitride (TaN, e.g., tantalum and nitrogen). Notably, tantalum nitride has similar advantages to those discussed with respect to niobium nitride. In some embodiments, oxygen migration mitigation layer 204 is or includes tantalum nitride such that oxygen migration mitigation layer 204 includes tantalum and nitrogen. In some embodiments oxygen migration mitigation layer 204 is or includes tantalum nitride at a stoichiometry of one or more of Ta₂N, TaN, or Ta₃N₅. In some embodiments, oxygen migration mitigation layer 204 is not less than 30 percent tantalum and not less than 45 percent nitrogen. In some embodiments, oxygen migration mitigation layer 204 is not less than 45 percent tantalum and not less than 45 percent nitrogen. In some embodiments, oxygen migration mitigation layer 204 is not less than 35 percent tantalum and not less than 60 percent nitrogen. In some embodiments, oxygen migration mitigation layer 204 is pure tantalum nitride with the sum of tantalum and nitrogen percentages being at least 99%. In some embodiments, oxygen migration mitigation layer 204 is not less than 32 percent tantalum and a balance (up to at least 99%) of nitrogen. In some embodiments, oxygen migration mitigation layer 204 is not less than 49 percent tantalum and a balance (up to at least 99%) of nitrogen. In some embodiments, oxygen migration mitigation layer 204 is not less than 35 percent tantalum and a balance (up to at least 99%) of nitrogen.

In some embodiments, oxygen migration mitigation layer 204 is or includes ruthenium oxide (RuO₂, e.g., ruthenium and oxygen). Ruthenium has similar advantages to those discussed with respect to niobium nitride. In some embodiments, oxygen migration mitigation layer 204 is or includes ruthenium oxide such that oxygen migration mitigation layer 204 includes ruthenium and oxygen. In some embodiments oxygen migration mitigation layer 204 is or includes ruthenium oxide at a stoichiometry of RuO₂. In some embodiments, oxygen migration mitigation layer 204 is not less than 30 percent ruthenium and not less than 60 percent oxygen. In some embodiments, oxygen migration mitigation layer 204 is ruthenium oxide. In some embodiments, oxygen migration mitigation layer 204 is ruthenium oxide with the sum of ruthenium and oxygen percentages being at least 99%. In some embodiments, oxygen migration mitigation layer 204 is not less than 32 percent ruthenium and a balance (up to at least 99%) of oxygen.

As shown, oxygen migration mitigation layer 204 may have a thickness t5 that may be any suitable thickness value. In some embodiments, thickness t5 of oxygen migration mitigation layer 204 is in the range of 2 to 6 nm. In some embodiments, thickness t5 of oxygen migration mitigation layer 204 is in the range of 2 to 4 nm. In some embodiments, thickness t5 of oxygen migration mitigation layer 204 is about 4 nm. In some embodiments, thickness t5 of oxygen migration mitigation layer 204 is not more than 5 nm.

FIG. 2C illustrates an example FE device structure 220 similar to FE device structure 210 after formation of top electrode 102. Top electrode 102 may be formed using any suitable technique or techniques such as those discussed herein below. Top electrode 102 may include any suitable conductive material such as a metal. In some embodiments, top electrode 102 is or includes a layer of titanium nitride (TiN, e.g., titanium and nitrogen). In some embodiments, bottom electrode is or includes tungsten (W), tantalum nitride (TaN, e.g., tantalum and nitrogen), niobium nitride (NbN, e.g., niobium and nitrogen), ruthenium (Ru), iridium (Ir), aluminum (Al), copper (Cu), titanium (Ti), cobalt (Co), chromium (Cr), molybdenum (Mo), nickel (Ni), gold (Au), or platinum (Pt) . . . . Top electrode 102 and bottom electrode 101 may be the same materials or they may be different.

As shown, top electrode 102 is on oxygen migration mitigation layer 204. As discussed, oxygen migration mitigation layer 204 may advantageously be metallic to decrease contact resistance to material stack 103. Furthermore, oxygen migration mitigation layer 204 reduces or eliminates any oxygen gettering by top electrode 102. As shown, top electrode 102 may have a thickness t6 that may be any suitable thickness value. In some embodiments, thickness t6 of top electrode 102 is in the range of 15 to 50 nm. In some embodiments, thickness t6 of top electrode 102 is in the range of 15 to 40 nm. In some embodiments, thickness t6 of top electrode 102 is about 30 nm. In some embodiments, thickness t6 of top electrode 102 is not more than 30 nm. In some embodiments, thickness t6 of top electrode 102 is in the range of 5 to 20 nm. In some embodiments, thickness t6 of top electrode 102 is in the range of 5 to 15 nm. In some embodiments, thickness t6 of top electrode 102 is about 10 nm. In some embodiments, thickness t6 of top electrode 102 is not more than 10 nm. Thickness t6 of top electrode 102 and thickness t1 of bottom electrode 101 may be the same or they may be different.

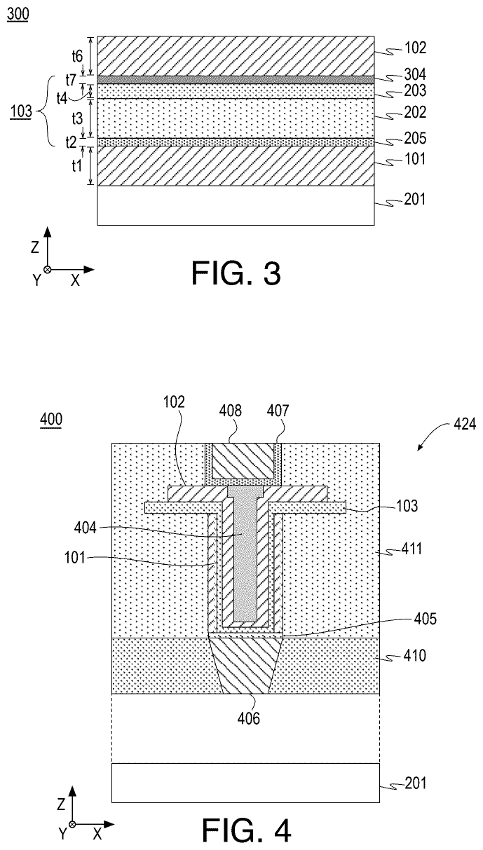

FIG. 3 illustrates an example FE device structure 300 similar to FE device structure 220 with an alternative (e.g., substantially pure or pure molybdenum, tungsten, ruthenium, or palladium) oxygen migration mitigation layer 304 in place of oxygen migration mitigation layer 204 in material stack 103, arranged in accordance with at least some implementations of the present disclosure. Oxygen migration mitigation layer 304 may be formed using any suitable technique or techniques such as those discussed herein below. Although characterized as an oxygen migration mitigation layer, oxygen migration mitigation layer 304 may be characterized simply as a material layer, material, layer, or the like. As discussed with respect to oxygen migration mitigation layer 204, oxygen migration mitigation layer 304 is on capping layer 203, and the discussed degradation of the ferroelectric behavior of FE hafnium oxide-based material layer 202 may be reduced or eliminated by the deployment of oxygen migration mitigation layer 304. In some embodiments, such degradation reduction or elimination is provided by the combination of capping layer 203 and oxygen migration mitigation layer 304.

In some embodiments, oxygen migration mitigation layer 304 is or includes one of molybdenum (Mo), tungsten (W), ruthenium (Ru), or palladium (Pd). Notably, molybdenum, tungsten, ruthenium, and palladium are substantially non-reactive metals that reduce or prevent oxygen scavenging during molybdenum, tungsten, ruthenium, or palladium metal deposition and reduces or eliminates oxygen diffusion from the underlying layers, particularly during deposition of top electrode 102 such as when titanium nitride (or other electrode material) is deposited.

Furthermore, as with niobium nitride, tantalum nitride, and ruthenium oxide, molybdenum, tungsten, ruthenium, and palladium are metallic materials suitable for subsequent formation of electrode 102 thereon. For example, oxygen migration mitigation layer 304 may be characterized as a portion of an electrode, and molybdenum, tungsten, ruthenium, and palladium do not increase the total oxide thickness of material stack 103. In some embodiments, oxygen migration mitigation layer 304 can be advantageously scaled to a thickness t7 of about 4 nm. In some embodiments, thickness t7 of oxygen migration mitigation layer 304 is in the range of 2 to 10 nm. In some embodiments, thickness t7 of oxygen migration mitigation layer 304 is in the range of 2 to 6 nm. In some embodiments, thickness t7 of oxygen migration mitigation layer 304 is about 4 nm. In some embodiments, thickness t7 of oxygen migration mitigation layer 304 is not more than 5 nm. In addition to scalability advantages, deployment of molybdenum, tungsten, ruthenium, or palladium provides increased device endurance.

As discussed, oxygen migration mitigation layer 304 is or includes molybdenum, tungsten, ruthenium, or palladium. In some embodiments, oxygen migration mitigation layer 304 is substantially pure molybdenum (i.e., not less than 95% molybdenum). In some embodiments, oxygen migration mitigation layer 304 is pure molybdenum (i.e., not less than 99% molybdenum). In some embodiments, oxygen migration mitigation layer 304 is not less than 99.5% molybdenum. In some embodiments, oxygen migration mitigation layer 304 is not less than 99.9% molybdenum.

In some embodiments, oxygen migration mitigation layer 304 is substantially pure tungsten (i.e., not less than 95% tungsten). In some embodiments, oxygen migration mitigation layer 304 is pure tungsten (i.e., not less than 99% tungsten). In some embodiments, oxygen migration mitigation layer 304 is not less than 99.5% tungsten. In some embodiments, oxygen migration mitigation layer 304 is not less than 99.9% tungsten.

In some embodiments, oxygen migration mitigation layer 304 is substantially pure ruthenium (i.e., not less than 95% ruthenium). In some embodiments, oxygen migration mitigation layer 304 is pure ruthenium (i.e., not less than 99% ruthenium). In some embodiments, oxygen migration mitigation layer 304 is not less than 99.5% ruthenium. In some embodiments, oxygen migration mitigation layer 304 is not less than 99.9% ruthenium.

In some embodiments, oxygen migration mitigation layer 304 is substantially pure palladium (i.e., not less than 95% palladium). In some embodiments, oxygen migration mitigation layer 304 is pure palladium (i.e., not less than 99% palladium). In some embodiments, oxygen migration mitigation layer 304 is not less than 99.5% palladium. In some embodiments, oxygen migration mitigation layer 304 is not less than 99.9% palladium.

As shown, top electrode 102 is on oxygen migration mitigation layer 304. As discussed, oxygen migration mitigation layer 304 may advantageously be metallic to decrease contact resistance to material stack 103, and oxygen migration mitigation layer 304 may reduce or eliminate any oxygen gettering by top electrode 102. Top electrode 102 may have any thickness t6 such as those discussed with respect to FIG. 2C.

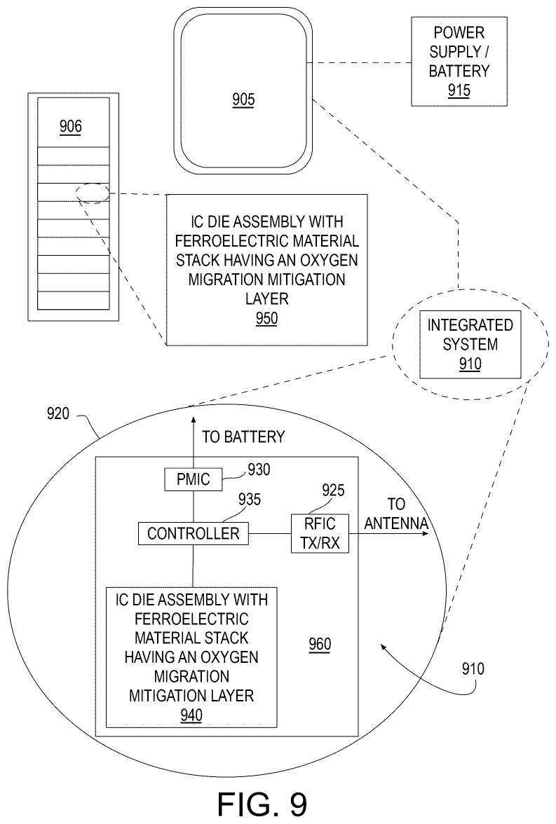

FIG. 4 illustrates a cross-sectional side view of an exemplary deep trench capacitor 400 having an oxide layer on a ferroelectric hafnium oxide-based material layer and an oxygen migration mitigation layer on the oxide layer, arranged in accordance with some embodiments of the disclosure. As shown, deep trench capacitor 400 and/or other components discussed herein may be deployed as part of an IC die 424, which is coupled to other components such as a power supply as is known in the art and as illustrated and discussed with respect to FIG. 9. In the example of FIG. 4, deep trench capacitor 400 may be deployed over a bit line (i.e., capacitor over bit line, COB). Deep trench capacitor 400 may have a U-shape (as shown) or a V-shape. As shown, deep trench capacitor 400 includes electrode 101, electrode 102, material stack 103 (illustrated as a single component for the sake of clarity), a metal via 404, a barrier layer 405, an interconnect 406, a barrier layer 407, and an interconnect 408. Electrode 101 is coupled to interconnect 406 via barrier layer 405 and electrode 102 is coupled to interconnect 408 via metal via 404 and barrier layer 407. Deep trench capacitor 400 is formed in insulator 411 (e.g., silicon oxide, SiO₂), interconnect 406 is embedded in insulator 410, and such components are formed over substrate 201.

Such components may include any characteristics discussed herein. For example, electrode 101 may be or include a layer of titanium nitride or other material discussed herein. Furthermore, material stack 103 may include optional seed layer 205 on electrode 101, FE hafnium oxide-based material layer 202 on seed layer 205 or on electrode 101, capping layer 203 on FE hafnium oxide-based material layer 202, and oxygen migration mitigation layer 204, 304 on capping layer 203. Electrode 102, which may be or include a layer of titanium nitride or other material discussed herein is on oxygen migration mitigation layer 204. In some embodiments, seed layer 205 is titanium oxide and FE hafnium oxide-based material layer 202 is lanthanum doped HZO. However, any materials discussed herein may be deployed. Oxygen migration mitigation layer 204, 304 may be niobium nitride, tantalum nitride, or ruthenium oxide as discussed with respect to oxygen migration mitigation layer 204 and FIGS. 2A to 2B or oxygen migration mitigation layer 304 may be tungsten, molybdenum, ruthenium, or palladium as discussed with respect to FIG. 3. Furthermore, the components of material stack 103 may have any characteristics discussed elsewhere herein. Notably, the architecture of deep trench capacitor 400 may offer the advantage or relatively large capacitor surface are relative to x-y plane layout area used by deep trench capacitor 400.

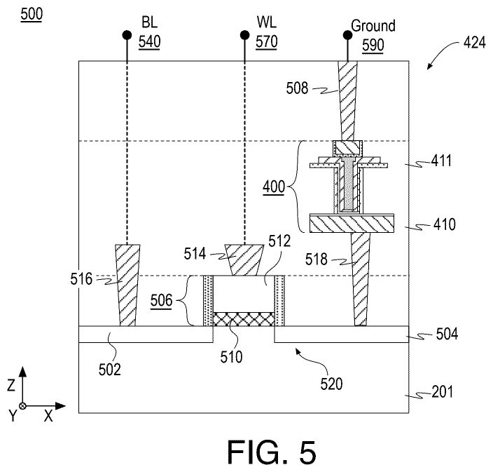

FIG. 5 illustrates a cross-section of an embedded dynamic random-access memory 500 including capacitor 400, arranged in accordance with some embodiments of the disclosure. Although illustrated with respect to deep trench capacitor 400 being deployed in embedded dynamic random-access memory 500, any capacitor or device structure discussed herein may be used. As shown, embedded dynamic random-access memory 500 includes a select transistor 520 coupled to a capacitor such as deep trench capacitor 400. Transistor 520 includes a source region 502, a drain region 504, and a gate 506. Transistor 520 further includes a gate contact 514 on and electrically coupled to gate 506, a source contact 516 on and electrically coupled to source region 502, and a drain contact 518 on and electrically coupled to drain region 504. In some embodiments, capacitor 400 is above transistor 520 such that electrode 101 is coupled to drain contact 518 and electrode 102 is coupled to a via 508. However, other architectures may be used.

In some embodiments, transistor 520 is a metal-oxide-semiconductor field-effect transistor (MOSFET or simply MOS transistors). Transistor 520 may be a planar transistor (as shown) or a nonplanar transistor such as a FinFET or a gate all around transistor such as a nanoribbon or nanowire transistor. Data is written into capacitor 400 as charge via a bit line (BL) 540 when access transistor 520 is turned on by applying a voltage on a word line WL 570. Interconnect 408 couples to a ground 590 through a metal via 508. In some embodiments, gate 506 is formed of at least two layers, gate dielectric layer 510 and gate electrode layer 512. Gate dielectric layer 510 may include one layer or a stack of layers including one or more of silicon dioxide and/or a high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. Gate electrode layer 512 is on gate dielectric layer 510 and may comprise of at least one a P-type work-function metal (e.g., ruthenium, palladium, platinum, cobalt, nickel, and conductive metal oxides, e.g., ruthenium oxide) or a N-type work-function metal (e.g., hafnium, zirconium, titanium, tantalum, aluminum, alloys of these metals, and carbides of these metals such as hafnium carbide, zirconium carbide, titanium carbide, tantalum carbide, and aluminum carbide), depending on whether the transistor is to be a PMOS or an NMOS transistor. In some embodiments, the gate electrode layer 512 may comprise of a stack of two or more metal layers, where one or more metal layers are work-function metal layers and at least one metal layer is a conductive fill layer.

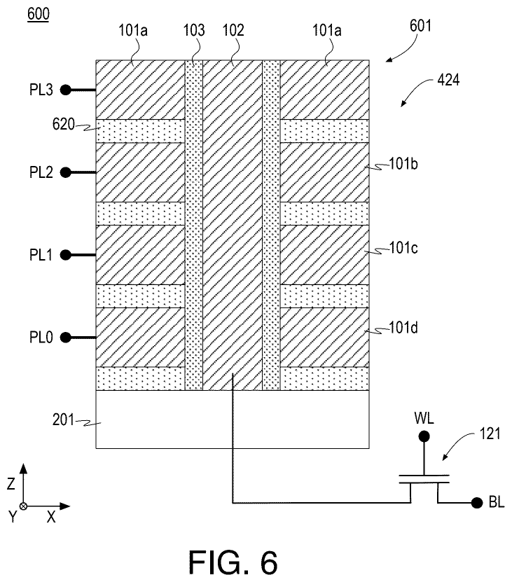

FIG. 6 illustrates a cross-sectional side view of a multiple capacitor stacked memory device 600 including capacitors having an oxide layer on a ferroelectric hafnium oxide-based material layer and an oxygen migration mitigation layer on the oxide layer, arranged in accordance with some embodiments of the disclosure. As shown in FIG. 6, memory device 600 includes multiple FE capacitors 601 having outer electrodes 101a-d, material stack 103, and a shared electrode 102. Memory device 600 includes a vertically aligned array of FE capacitors 601 such that each FE capacitor 601 includes an electrode 101a-d, and a portion of electrode 102, which extends vertically through FE capacitors 601, electrodes 101a-d, and material stack 103. Electrode 102 electrically connects to select transistor 121, as discussed herein. Insulators 620 surround electrode 102 and vertically separate and electrically isolate electrodes 101a-d.

Electrodes 101a-d may each be part of an integrated structure coupled to a corresponding plate line. For example, material stack 103 may be on an inner surface of a corresponding plate line, which is integral with corresponding electrodes 101a-d. In the example of FIG. 6, material stack 103 is on an inner surface of plate lines PL0, PL1, PL2, PL3, which are each integral with a corresponding electrodes 101a-d.

Such components may include any characteristics discussed herein. For example, electrodes 101a-d may be or include a layer of titanium nitride or other material discussed herein with respect to electrode 101. Furthermore, material stack 103 may include optional seed layer 205 on electrodes 101a-d, FE hafnium oxide-based material layer 202 on seed layer 205 or on electrodes 101a-d, capping layer 203 on FE hafnium oxide-based material layer 202, and oxygen migration mitigation layer 204, 304 on capping layer 203. Electrode 102, which may be or include a layer of titanium nitride or other material discussed herein is on oxygen migration mitigation layer 204. In some embodiments, seed layer 205 is titanium oxide and FE hafnium oxide-based material layer 202 is lanthanum doped HZO. However, any materials discussed herein may be deployed. Oxygen migration mitigation layer 204, 304 may be niobium nitride, tantalum nitride, or ruthenium oxide as discussed with respect to oxygen migration mitigation layer 204 and FIGS. 2A to 2B or oxygen migration mitigation layer 304 may be tungsten, molybdenum, ruthenium, or palladium as discussed with respect to FIG. 3. Furthermore, the components of material stack 103 may have any characteristics discussed elsewhere herein.

Transistor 121 controls access to the memory array by electrically connecting (or not) electrode 102 to a bit line BL connected at a drain contact of transistor 121. When transistor 121 conducts, electrode 102 on electrically connected to bit line BL. The conduction of transistor 121 is controlled by the voltage signal applied to a gate electrode by a word line WL. Since electrode 102 is shared for all FE capacitors 601 in the group, any bit stored in any of FE capacitors 601 is accessible by single transistor 121. With transistor 121 accessing the entire memory array of FE capacitors 601, individual control of FE capacitors 601 is by electrodes 101a-d using plate lines PL0-PL3 in concert with transistor 121.

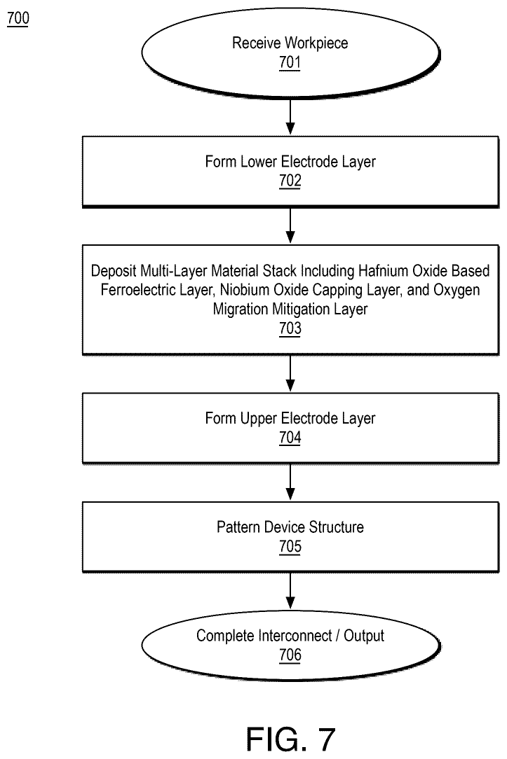

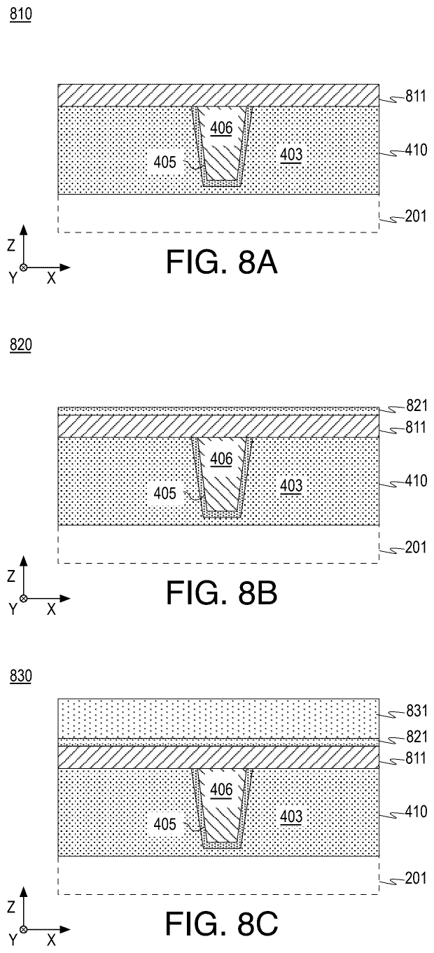

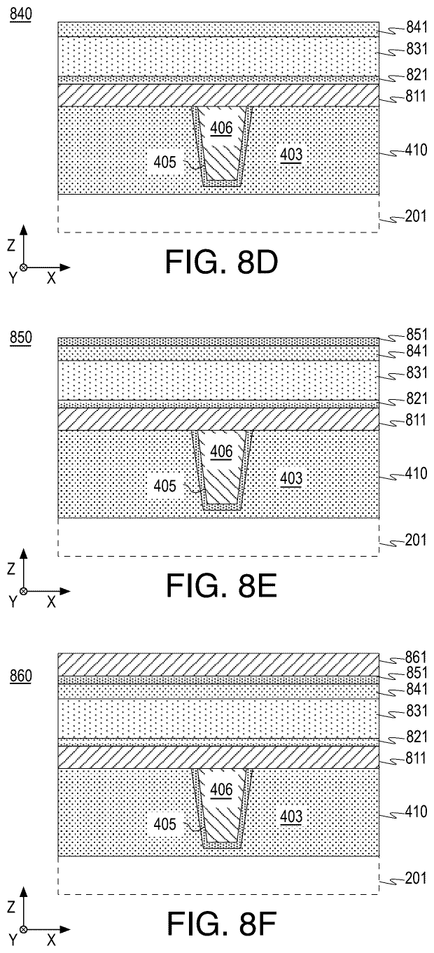

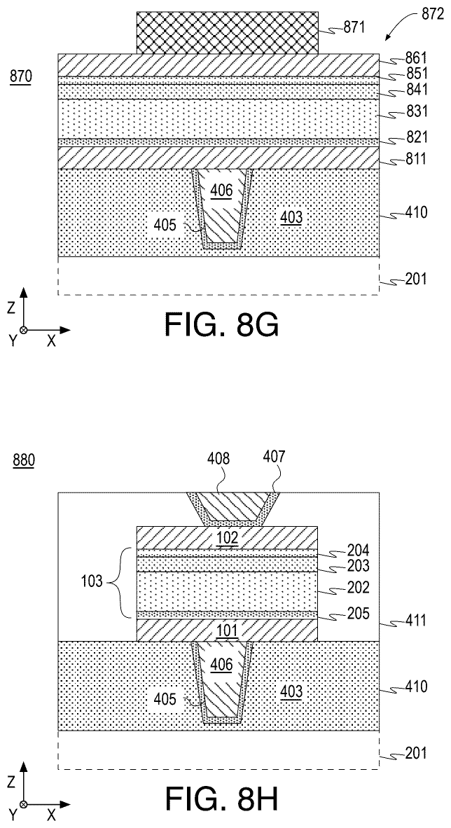

FIG. 7 is a flow diagram illustrating methods 700 for forming a device including an oxide layer on a ferroelectric hafnium oxide-based material layer and an oxygen migration mitigation layer on the oxide layer, arranged in accordance with some embodiments of the disclosure. Methods 700 may be practiced, for example, to fabricate any of the FE devices discussed herein. Although illustrated with respect to fabricating an FE capacitor, methods 700 may be used to fabricate any device that includes an FE material stack such as an FeFET, an FTJ, or the like. FIGS. 8A, 8B, 8C, 8D, 8E, 8F, 8G, and 8H are cross-sectional views of a device structure evolving as methods 700 are practiced, arranged in accordance with some embodiments of the disclosure.

Methods 700 begin at input operation 701 where a workpiece including one or more material layers of a monolithic IC is received. In some embodiments, the workpiece is a large format (e.g., 300-450 mm) wafer and includes at least a device coupling or metallization layer on a working surface of the wafer. Processing continues at operation 702, where a lower electrode layer is formed using any suitable technique or techniques such as blanket deposition techniques including atomic layer deposition (ALD) processing. In the example illustrated in FIG. 8A, device structure 810 includes an interconnect 406 over substrate 201, with interconnect 406 on a barrier layer 405. Interconnect 406 and barrier layer 405 are embedded within insulator 410. Insulator 410 may be silicon dioxide, silicon nitride, silicon carbide, or a low-k dielectric such as carbon doped silicon oxide. Barrier layer 405 may include tantalum, tantalum nitride, or ruthenium, for example. Interconnect 406 includes a fill metal that may be cobalt, copper, tungsten, or ruthenium, for example.

As shown in FIG. 8A, device structure 810 also includes a lower electrode material layer 811 (as formed at operation 702), which is to become electrode 101 of device structure 880. Electrode material layer 811 may include any material or materials as discussed herein with respect to electrodes 101, 102. In some embodiments, electrode material layer 811 is titanium nitride (e.g., includes titanium and nitrogen). However, other materials discussed herein may be used. Electrode material layer 811 may be formed using any suitable technique or techniques such as blanket deposition. The blanket deposition may be performed with an ALD process, for example.

Returning to FIG. 7, methods 700 continue at operation 703, where a multi-layer FE material stack is blanket deposited adjacent the lower electrode material layer. The multi-layer FE material stack may include a seed layer, a hafnium oxide-based FE material layer, a capping layer, and an oxygen migration mitigation layer, for example. Any deposition technique or techniques known to be suitable for deposition of the materials of a multi-layer FE material stack may be practiced at operation 703, but in some exemplary embodiments, one or more layers of the multi-layer FE material stack are deposited with an ALD process. In some embodiments, multiple adjacent layers of the multi-layer FE material stack (and/or the layers of the lower and upper electrode) are formed while the workpiece is in the same process chamber and without breaking vacuum of the process chamber. In some embodiments, forming the oxygen migration mitigation layer and forming the capping oxide layer includes atomic layer deposition (ALD) of the oxygen migration mitigation layer and the capping oxide layer within a continuously sealed process chamber. In some embodiments, such processing is deployed to form a niobium nitride oxygen migration mitigation layer.

FIG. 8B illustrates an example device structure 820 similar to device structure 810 after blanket deposition of a seed material layer 821. Seed material layer 821 may include any material or materials as discussed herein with respect to seed layer 205. In some embodiments, seed material layer 821 is titanium oxide (e.g., includes titanium and oxygen). As discussed, seed material layer 821 is optional but may advantageously promote the orthorhombic phase of a subsequent hafnium oxide-based FE material layer. Seed material layer 821 may be formed using any suitable blanket deposition technique or techniques such as an ALD process, for example.

FIG. 8C illustrates an example device structure 830 similar to device structure 820 after blanket deposition of a FE hafnium oxide-based material layer 831. FE hafnium oxide-based material layer 831 may include any material or materials as discussed herein with respect to FE hafnium oxide-based material layer 202. In some embodiments, FE hafnium oxide-based material layer 831 is HZO (e.g., includes hafnium, zirconium, and oxygen) or HZO doped with one or more additional elements such as silicon, lanthanum, aluminum, niobium, germanium, or scandium. As discussed, it is desirable for FE hafnium oxide-based material layer 831 to include a large proportion of an orthorhombic crystalline structure and other materials and process parameters and procedures are selected to increase the proportion of the orthorhombic crystalline structure of FE hafnium oxide-based material layer 831. FE hafnium oxide-based material layer 831 may be formed using any suitable technique or techniques such as an ALD process, for example.

FIG. 8D illustrates an example device structure 840 similar to device structure 830 after blanket deposition of a capping material layer 841 on FE hafnium oxide-based material layer 831. Capping material layer 841 may include any material or materials as discussed herein with respect to capping layer 203. In some embodiments, capping material layer 841 is niobium oxide (e.g., includes niobium and oxygen). For example, capping material layer 841 may be one or a combination of niobium pentoxide and niobium dioxide. In some embodiments, capping material layer 841 is tantalum oxide (e.g., includes tantalum and oxygen). For example, capping material layer 841 may be tantalum pentoxide. As discussed, capping material layer 841 may provide oxygen for oxygen vacancies in FE hafnium oxide-based material layer 831. Capping material layer 841 may be formed using any suitable technique or techniques such as an ALD process, for example.

FIG. 8E illustrates an example device structure 850 similar to device structure 840 after blanket deposition of an oxygen migration mitigation material layer 851 on capping material layer 841. Oxygen migration mitigation material layer 851 may include any material or materials as discussed herein with respect to oxygen migration mitigation layer 204. In some embodiments, oxygen migration mitigation material layer 851 is niobium nitride (e.g., includes niobium and nitrogen), tantalum nitride (e.g., includes tantalum and nitrogen), or ruthenium oxide (e.g., includes ruthenium and oxygen). In some embodiments, oxygen migration mitigation material layer 851 is substantially pure or pure molybdenum. In some embodiments, oxygen migration mitigation material layer 851 is substantially pure or pure tungsten. In some embodiments, oxygen migration mitigation material layer 851 is substantially pure or pure ruthenium. In some embodiments, oxygen migration mitigation material layer 851 is substantially pure or pure palladium. For example, oxygen migration mitigation material layer 851 may provide a barrier from oxygen diffusion from one or both of capping material layer 841 and FE hafnium oxide-based material layer 831. Oxygen migration mitigation material layer 851 may be formed using any suitable technique or techniques such as an ALD process, for example. In some embodiments, the ALD process used to form capping material layer 841 and the ALD process used to form oxygen migration mitigation material layer 851 is within a continuously sealed process chamber with the material formed controlled by the process gas introduced into the continuously sealed process chamber, for example.

Returning to FIG. 7, processing continues at operation 704, where an upper electrode material layer is blanket deposited on the multi-layer FE material stack and, in particular, on the oxygen migration mitigation material layer. Although any deposition technique or techniques known to be suitable for such deposition may be practiced at operation 704, in some exemplary embodiments, the upper electrode material layer is deposited with an ALD process.

FIG. 8F illustrates an example device structure 860 similar to device structure 850 after blanket deposition of an electrode material layer 861 on oxygen migration mitigation material layer 851. Upper electrode material layer 861 is to become electrode 102 of device structure 880. Electrode material layer 861 may include any material or materials as discussed herein with respect to electrodes 101, 102. In some embodiments, electrode material layer 861 is titanium nitride (e.g., includes titanium and nitrogen). However, any materials discussed herein may be used. Electrode material layer 861 may be formed using any suitable technique or techniques such as an ALD process, for example.

Returning to FIG. 7, methods 700 continue at operation 705, where the device material layers formed at operations 702-704 are patterned with any subtractive process(es) suitable for the various material layer compositions. Following device patterning, any remaining interconnect levels of the IC may be completed, and the resultant structure may be output at operation 706. For example, the upper electrode of the device may be connected to other circuit nodes with an upper-level metallization.

FIG. 8G illustrates an example device structure 870 similar to device structure 860 after patterning a mask 871 on electrode material layer 861. Mask 871 defines a polygon area and position of a device for patterning material layer stack 872, for example, relative to interconnect 406. Mask 871 may be formed with any lithographic process(es) as embodiments are not limited in this respect. FIG. 8H illustrates an example device structure 880 similar to device structure 870 after the patterning of material layer stack 872. In some embodiments, material layer stack 872 may be patterned with one or more plasma etch processes. Such etch processing defines sidewalls into the various material layers 811, 821, 831, 841, 851, 861 to form electrode 101, material stack 103, and electrode 102, respectively. FIG. 8H further illustrates an example where an upper-level interconnect 408 and barrier layer 407 has been fabricated in contact with electrode 102, with upper-level interconnect 408, barrier layer 407, electrode 101, material stack 103, and electrode 102 buried in insulator 411. Barrier layer 407 may provide for improved adhesion and may include, for example, tantalum, tantalum nitride, or ruthenium in contact with electrode 102. Interconnect 408 may include any suitable fill metal such as cobalt, tungsten, or copper.

Although illustrated with respect to device structure 880 being a thin film capacitor, methods 700 may be extended for use to fabricate other device architectures such as deep trench capacitor 400, multiple capacitor stacked memory device 600, FeFETs, FTJs, or others.

FIG. 9 illustrates exemplary systems employing an IC die having an oxide layer on a ferroelectric hafnium oxide-based material layer and an oxygen migration mitigation layer on the oxide layer, in accordance with some embodiments. The system may be a mobile computing platform 905 and/or a data server machine 906, for example. Either may employ a memory cell, capacitor, FeFET, FTJ or the like having an FE material stack as described elsewhere herein. Server machine 906 may be any commercial server, for example including any number of high-performance computing platforms disposed within a rack and networked together for electronic data processing, which in the exemplary embodiment includes an IC die assembly 950 with an IC die assembly including a multi-layer FE material stack as described elsewhere herein. Mobile computing platform 905 may be any portable device configured for each of electronic data display, electronic data processing, wireless electronic data transmission, or the like. For example, mobile computing platform 905 may be any of a tablet, a smart phone, a laptop computer, etc., and may include a display screen (e.g., a capacitive, inductive, resistive, or optical touchscreen), a chip-level or package-level integrated system 910, and a battery 915. Although illustrated with respect to mobile computing platform 905, in other examples, chip-level or package-level integrated system 910 and a power supply/battery 915 may be implemented in a desktop computing platform, an automotive computing platform, an internet of things platform, or the like. As discussed below, in some examples, the disclosed systems may include a sub-system 960 such as a system on a chip (SOC) or an integrated system of multiple ICs, which is illustrated with respect to mobile computing platform 905.

Whether disposed within integrated system 910 illustrated in expanded view 920 or as a stand-alone packaged device within data server machine 906, sub-system 960 may include memory circuitry and/or processor circuitry 940 (e.g., RAM, a microprocessor, a multi-core microprocessor, graphics processor, etc.), a power management integrated circuit (PMIC) 930, a controller 935, and a radio frequency integrated circuit (RFIC) 925 (e.g., including a wideband RF transmitter and/or receiver (TX/RX)). As shown, one or more IC dice, such as memory circuitry and/or processor circuitry 940 may be assembled and implemented such that one or more have a multi-layer FE material stack as described herein. In some embodiments, RFIC 925 includes a digital baseband and an analog front end module further comprising a power amplifier on a transmit path and a low noise amplifier on a receive path). Functionally, PMIC 930 may perform battery power regulation, DC-to-DC conversion, etc., and so has an input coupled to power supply/battery 915, and an output providing a current supply to other functional modules. As further illustrated in FIG. 9, in the exemplary embodiment, RFIC 925 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 940 may provide memory functionality for sub-system 960, high level control, data processing and the like for sub-system 960. In alternative implementations, each of the SOC modules may be integrated onto separate ICs coupled to a package substrate, interposer, or board.

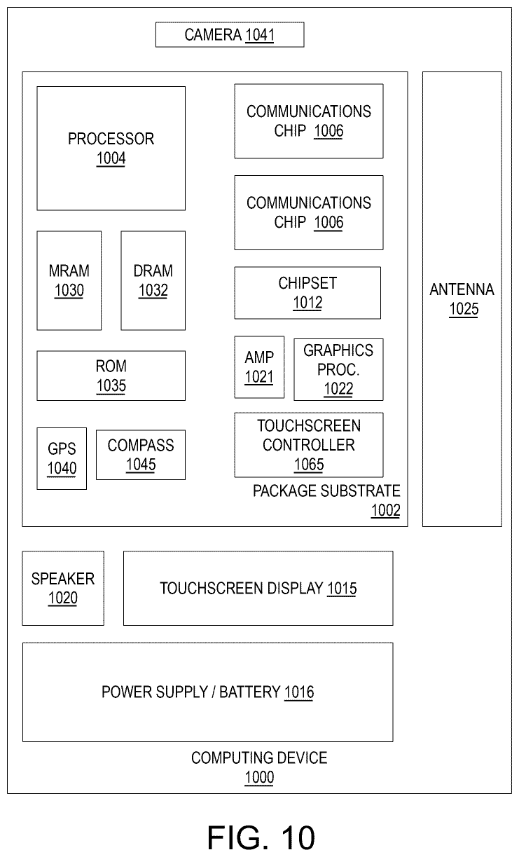

FIG. 10 is a functional block diagram of an electronic computing device 1000, in accordance with some embodiments. For example, device 1000 may, via any suitable component therein, employ a multi-layer FE material stack in accordance with any embodiments described elsewhere herein. Device 1000 further includes a motherboard or package substrate 1002 hosting a number of components, such as, but not limited to, a processor 1004 (e.g., an applications processor). Processor 1004 may be physically and/or electrically coupled to package substrate 1002. In some examples, processor 1004 is within an IC assembly that includes a multi-layer FE material stack as described elsewhere herein. In general, the term “processor” or “microprocessor” may refer to any device or portion of a device that processes electronic data from registers and/or memory to transform that electronic data into other electronic data that may be further stored in registers and/or memory.

In various examples, one or more communication chips 1006 may also be physically and/or electrically coupled to the package substrate 1002. In further implementations, communication chips 1006 may be part of processor 1004. Depending on its applications, computing device 1000 may include other components that may or may not be physically and electrically coupled to package substrate 1002. These other components include, but are not limited to, volatile memory (e.g., DRAM 1032), non-volatile memory (e.g., ROM 1035), flash memory (e.g., NAND or NOR), magnetic memory (MRAM 1030), a graphics processor 1022, a digital signal processor, a crypto processor, a chipset 1012, an antenna 1025, touchscreen display 1015, touchscreen controller 1065, power supply/battery 1016, audio codec, video codec, power amplifier 1021, global positioning system (GPS) device 1040, compass 1045, accelerometer, gyroscope, speaker 1020, camera 1041, and mass storage device (such as hard disk drive, solid-state drive (SSD), compact disk (CD), digital versatile disk (DVD), and so forth, or the like.

Communication chips 1006 may enable wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chips 1006 may implement any of a number of wireless standards or protocols, including, but not limited to, those described elsewhere herein. As discussed, computing device 1000 may include a plurality of communication chips 1006. For example, a first communication chip may be dedicated to shorter-range wireless communications, such as Wi-Fi and Bluetooth, and a second communication chip may be dedicated to longer-range wireless communications such as GPS, EDGE, GPRS, CDMA, WiMAX, LTE, Ev-DO, and others.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first layer adjacent a first electrode, the first layer comprising hafnium and oxygen, a second layer on the first layer, the second layer comprising oxygen and niobium or tantalum, a third layer on the second layer, the third layer comprising molybdenum, tungsten, ruthenium, palladium, niobium and nitrogen, tantalum and nitrogen, or ruthenium and oxygen, and a second electrode on the third layer.

In one or more second embodiments, further to the first embodiments, the second layer comprises not less than 60 percent oxygen.

In one or more third embodiments, further to the first or second embodiments, the second layer comprises not less than 70 percent oxygen.

In one or more fourth embodiments, further to the first through third embodiments, the third layer comprises pure molybdenum, pure tungsten, pure ruthenium, or pure palladium.

In one or more fifth embodiments, further to the first through fourth embodiments, the third layer comprises not less than 45 percent niobium and not less than 45 percent nitrogen.

In one or more sixth embodiments, further to the first through fifth embodiments, the third layer comprises not less than 30 percent tantalum and not less than 45 percent nitrogen.

In one or more seventh embodiments, further to the first through sixth embodiments, the third layer comprises not less than 30 percent ruthenium and not less than 60 percent oxygen.

In one or more eighth embodiments, further to the first through seventh embodiments, the first electrode or the second electrode comprises titanium and nitrogen, tantalum and nitrogen, niobium and nitrogen, ruthenium, tungsten, or molybdenum, the apparatus further comprising a fourth layer comprising oxygen and one of titanium, aluminum, vanadium, tantalum, silicon, or molybdenum, wherein the fourth layer is on the first electrode and the first layer is on the fourth layer.

In one or more ninth embodiments, further to the first through eighth embodiments, the first layer further comprises zirconium, silicon, lanthanum, aluminum, niobium, germanium, or scandium.

In one or more tenth embodiments, further to the first through ninth embodiments, an integrated circuit (IC) die comprises the first electrode, the first layer, the second layer, the third layer, and the second electrode, the apparatus further comprising a power supply coupled to the IC die.

In one or more eleventh embodiments, an apparatus comprises a first electrode, a ferroelectric material adjacent the first electrode, the ferroelectric material comprising hafnium, oxygen, and a dopant, a first layer on the ferroelectric material, the first layer comprising not less than 30 percent niobium or tantalum, and not less than 60 percent oxygen, a second layer on the first layer, the second layer comprising pure molybdenum, pure tungsten, pure ruthenium, pure palladium, not less than 45 percent niobium and not less than 45 percent nitrogen, not less than 30 percent tantalum and not less than 45 percent nitrogen, or not less than 30 percent ruthenium and not less than 60 percent oxygen, a second electrode on the second layer.

In one or more twelfth embodiments, further to the eleventh embodiments, the first layer comprises not less than 70 percent oxygen.

In one or more thirteenth embodiments, further to the eleventh or twelfth embodiments, the ferroelectric material is on the first electrode.

In one or more fourteenth embodiments, further to the eleventh through thirteenth embodiments, the apparatus further comprises a third layer comprising oxygen and one of titanium, aluminum, vanadium, tantalum, silicon, or molybdenum, wherein the third layer is on the first electrode and the ferroelectric material is on the third layer.

In one or more fifteenth embodiments, further to the eleventh through fourteenth embodiments, the second layer comprises pure niobium nitride or pure tantalum nitride.

In one or more sixteenth embodiments, further to the eleventh through fifteenth embodiments, an integrated circuit (IC) die comprises the first electrode, the ferroelectric material, the first layer, the second layer, and the second electrode, the apparatus further comprising a power supply coupled to the IC die.

In one or more seventeenth embodiments, a system comprises an IC die comprising any of the apparatuses of the first through sixteenth embodiments, the IC die further including a transistor coupled to one of the first or second electrodes.

In one or more eighteenth embodiments, a method comprises forming a ferroelectric material layer adjacent a first electrode, the ferroelectric material layer comprising hafnium, oxygen, and a dopant, forming a first layer on the ferroelectric material layer, the first layer comprising not less than 30 percent niobium or tantalum, and not less than 60 percent oxygen, forming a second layer on the first layer, the second layer comprising pure molybdenum, pure tungsten, pure ruthenium, pure palladium, not less than 45 percent niobium and not less than 45 percent nitrogen, not less than 30 percent tantalum and not less than 45 percent nitrogen, or not less than 30 percent ruthenium and not less than 60 percent oxygen, and forming a second electrode on the second layer.

In one or more nineteenth embodiments, further to the eighteenth embodiments, said forming the second layer and said forming the first layer comprises atomic layer deposition of the second layer and the first layer within a continuously sealed process chamber.

In one or more twentieth embodiments, further to the eighteenth or nineteenth embodiments, the ferroelectric material layer is formed on the first electrode.

In one or more twenty-first embodiments, further to the twentieth through third embodiments, the method further comprises forming a third layer on the first electrode, the third layer comprising oxygen and one of titanium, aluminum, vanadium, tantalum, silicon, or molybdenum, wherein the ferroelectric material layer is formed on the third layer.

However, the above embodiments are not limited in this regard and, in various implementations, the above embodiments may include the undertaking of only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first layer adjacent a first electrode, the first layer comprising hafnium and oxygen;
a second layer on the first layer, the second layer comprising oxygen and niobium or tantalum;
a third layer on the second layer, the third layer comprising molybdenum, tungsten, ruthenium, palladium, niobium and nitrogen, tantalum and nitrogen, or ruthenium and oxygen; and
a second electrode on the third layer.

2. The apparatus of claim 1, wherein the second layer comprises not less than 60 percent oxygen.

3. The apparatus of claim 1, wherein the second layer comprises not less than 70 percent oxygen.

4. The apparatus of claim 1, wherein the third layer comprises pure molybdenum, pure tungsten, pure ruthenium, or pure palladium.

5. The apparatus of claim 1, wherein the third layer comprises not less than 45 percent niobium and not less than 45 percent nitrogen.

6. The apparatus of claim 1, wherein the third layer comprises not less than 30 percent tantalum and not less than 45 percent nitrogen.

7. The apparatus of claim 1, wherein the third layer comprises not less than 30 percent ruthenium and not less than 60 percent oxygen.

8. The apparatus of claim 1, wherein the first electrode or the second electrode comprises titanium and nitrogen, tantalum and nitrogen, niobium and nitrogen, ruthenium, tungsten, or molybdenum, the apparatus further comprising a fourth layer comprising oxygen and one of titanium, aluminum, vanadium, tantalum, silicon, or molybdenum, wherein the fourth layer is on the first electrode and the first layer is on the fourth layer.

9. The apparatus of claim 1, wherein the first layer further comprises zirconium, silicon, lanthanum, aluminum, niobium, germanium, or scandium.

10. The apparatus of claim 1, wherein an integrated circuit (IC) die comprises the first electrode, the first layer, the second layer, the third layer, and the second electrode, the apparatus further comprising a power supply coupled to the IC die.

11. An apparatus, comprising:
a first electrode;
a ferroelectric material adjacent the first electrode, the ferroelectric material comprising hafnium, oxygen, and a dopant;
a first layer on the ferroelectric material, the first layer comprising not less than 30 percent niobium or tantalum, and not less than 60 percent oxygen;
a second layer on the first layer, the second layer comprising pure molybdenum, pure tungsten, pure ruthenium, pure palladium, not less than 45 percent niobium and not less than 45 percent nitrogen, not less than 30 percent tantalum and not less than 45 percent nitrogen, or not less than 30 percent ruthenium and not less than 60 percent oxygen; and
a second electrode on the second layer.

12. The apparatus of claim 11, wherein the first layer comprises not less than 70 percent oxygen.

13. The apparatus of claim 11, wherein the ferroelectric material is on the first electrode.

14. The apparatus of claim 11, further comprising:
a third layer comprising oxygen and one of titanium, aluminum, vanadium, tantalum, silicon, or molybdenum, wherein the third layer is on the first electrode and the ferroelectric material is on the third layer.

15. The apparatus of claim 11, wherein the second layer comprises pure niobium nitride or pure tantalum nitride.

16. The apparatus of claim 11, wherein an integrated circuit (IC) die comprises the first electrode, the ferroelectric material, the first layer, the second layer, and the second electrode, the apparatus further comprising a power supply coupled to the IC die.

17. A method, comprising:
forming a ferroelectric material layer adjacent a first electrode, the ferroelectric material layer comprising hafnium, oxygen, and a dopant;
forming a first layer on the ferroelectric material layer, the first layer comprising not less than 30 percent niobium or tantalum, and not less than 60 percent oxygen;
forming a second layer on the first layer, the second layer comprising pure molybdenum, pure tungsten, pure ruthenium, pure palladium, not less than 45 percent niobium and not less than 45 percent nitrogen, not less than 30 percent tantalum and not less than 45 percent nitrogen, or not less than 30 percent ruthenium and not less than 60 percent oxygen; and
forming a second electrode on the second layer.

18. The method of claim 17, wherein said forming the second layer and said forming the first layer comprises atomic layer deposition of the second layer and the first layer within a continuously sealed process chamber.

19. The method of claim 17, wherein the ferroelectric material layer is formed on the first electrode.

20. The method of claim 17, further comprising:
forming a third layer on the first electrode, the third layer comprising oxygen and one of titanium, aluminum, vanadium, tantalum, silicon, or molybdenum, wherein the ferroelectric material layer is formed on the third layer.
